(19) United States
(12) Patent Application Publication
(10) Pub. No.: US 2024/0274548 A1
(43) Pub. Date: Aug. 15, 2024

(54) ELECTRONIC DEVICE AND METHOD FOR MANUFACTURING ELECTRONIC DEVICE

(71) Applicant: Innolux Corporation, Miaoli County (TW)

(72) Inventors: Kuo-Liang Chuang, Miaoli County (TW); Shu-Lan Chen, Miaoli County (TW); Chiu-Lien Yang, Miaoli County (TW); Sheng-Nan Fan, Miaoli County (TW); Shih-Hsiung Wu, Miaoli County (TW); Feng-Yu Lin, Miaoli County (TW)

(73) Assignee: Innolux Corporation, Miaoli County (TW)

(21) Appl. No.: 18/645,408

(22) Filed: Apr. 25, 2024

Related U.S. Application Data
(63) Continuation of application No. 16/994,680, filed on Aug. 17, 2020.

(30) Foreign Application Priority Data
Sep. 2, 2019 (CN) 201910822995.2

(51) Int. Cl. H01L 23/552; G02F 1/1335; H01L 27/12

(52) U.S. Cl. CPC H01L 23/552; G02F 1/133512; H01L 27/1214; H01L 27/1259

(57) ABSTRACT

An electronic device and a method for manufacturing the same are provided. The electronic device includes a first substrate, a second substrate disposed opposite to the first substrate, a first light-shielding strip disposed on the first substrate, a second light-shielding strip disposed between the first substrate and the second substrate and color filter patterns disposed on the second light-shielding strip. An overlapping region is the first light-shielding strip overlapping the second light-shielding strip and has a total thickness, a first non-overlapping region of the first light-shielding strip and a second non-overlapping region of the second light-shielding strip are outside the overlapping region, the second light-shielding strip in the second non-overlapping region has a thickness different from the total thickness. In a cross-section view, a part of the color filter patterns includes a convex portion corresponding to the first or the second light-shielding strip.

### CROSS-REFERENCE TO RELATED APPLICATION

This application is a continuation application of and claims the priority benefit of a prior application Ser. No. 16/994,680, filed on Aug. 17, 2020, which claims the priority benefit of China application serial no. 201910822995.2, filed on Sep. 2, 2019. The entirety of each of the above-mentioned patent applications is hereby incorporated by reference herein and made a part of this specification.

### BACKGROUND

### Technical Field

The disclosure relates to an electronic device and a method for manufacturing the electronic device, and in particular to, an electronic device having a light-shielding strip.

### Description of Related Art

Lithography and/or an etching process is an important process for manufacturing an electronic device. As the market demands for the electronic device constantly increase, the technology of lithography and/or the etching process is constantly improving. However, lithography and/or the etching process sometimes cannot be used to manufacture desired products when high resolution products are manufactured. Therefore, quality of electronic devices still needs to be improved.

### SUMMARY

The disclosure is directed to an electronic device having a light-shielding strip.

According to embodiments of the disclosure, the electronic device includes a first substrate, a second substrate, a first light-shielding strip, a second light-shielding strip; and a plurality of color filter patterns disposed on the second light-shielding strip. The second substrate is disposed opposite to the first substrate. The first light-shielding strip is disposed on the first substrate, and the first light-shielding strip extends along a first direction. The second light-shielding strip is disposed between the first substrate and the second substrate. The second light-shielding strip extends along a second direction, and the first direction is different from the second direction. A portion of the first light-shielding strip overlapping a portion of the second light-shielding strip is defined as an overlapping region, the other portion of the first light-shielding strip outside the overlapping region is defined as a first non-overlapping region, and the other portion of the second light-shielding strip outside the overlapping region is defined as a second non-overlapping region. The overlapping region has a total thickness, the second light-shielding strip has a thickness in the second non-overlapping region, and the total thickness is different from the thickness. In a cross-section view, a part of the plurality of color filter patterns includes a convex portion corresponding to the first light-shielding strip or the second light-shielding strip.

According to the embodiments of the disclosure, a method for manufacturing an electronic device includes the following steps: disposing a first light-shielding strip on a first substrate; providing a second substrate, and disposing a second light-shielding strip between first substrate and the second substrate; forming a plurality of color filter patterns on the second light-shielding strip; and pairing the first substrate with the second substrate. A portion of the first light-shielding strip overlapping a portion of the second light-shielding strip is defined as an overlapping region. The other portion of the first light-shielding strip outside the overlapping region is defined as a first non-overlapping region. The other portion of the second light-shielding strip outside the overlapping region is defined as a second non-overlapping region. The overlapping region has a total thickness, the second light-shielding strip has a thickness in the second non-overlapping region, and the total thickness is different from the thickness. In a cross-section view, a part of the plurality of color filter patterns includes a convex portion corresponding to the first light-shielding strip or the second light-shielding strip.

Based on the above, the electronic device of the embodiment of the disclosure separately disposes the first light-shielding strip and the second light-shielding strip. In this way, a region (which may be understood as a pixel region) surrounded by the first light-shielding strip and the second light-shielding strip may have a desired contour. Therefore, the electronic device of the embodiment of the disclosure has ideal quality.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic side view of an electronic device according to an embodiment of the disclosure.

FIG. 2 is a schematic top view of an electronic device according to an embodiment of the disclosure.

FIG. 3 is a schematic cross-sectional view of an electronic device according to an embodiment of the disclosure.

FIG. 4 is a schematic diagram of an electronic device according to another embodiment of the disclosure.

FIG. 5 is a schematic diagram showing a stacking order of members in FIG. 4.

FIG. 6 is a schematic cross-sectional view of a member of FIG. 4.

FIG. 7 is a schematic cross-sectional view of an electronic device according to another embodiment of the disclosure.

FIG. 8 is a schematic cross-sectional view of an electronic device according to yet another embodiment of the disclosure.

FIG. 9 is a schematic cross-sectional view of an electronic device according to a further embodiment of the disclosure.

FIG. 10 is a schematic cross-sectional view of an electronic device according to still yet another embodiment of the disclosure.

FIG. 11 is a schematic cross-sectional view of an electronic device according to still another embodiment of the disclosure.

FIG. 12 is a schematic cross-sectional view of an active component array substrate according to an embodiment of the disclosure.

FIG. 13A is a schematic top view of an electronic device according to still another embodiment of the disclosure.

FIG. 13B is a schematic perspective view of a structure of FIG. 13A taken along line II-II.

FIG. 14 is a schematic cross-sectional view of a structure of FIG. 13A taken along line II-II.

FIG. 15 is a schematic top view of an electronic device according to another embodiment of the disclosure.

FIG. 16 is a schematic flowchart of a method for manufacturing an electronic device according to an embodiment of the disclosure.

### DESCRIPTION OF THE EMBODIMENTS

A structure (or layer, component, substrate) being located on another structure (or layer, component, substrate) described in the disclosure may mean that two structures are adjacent and directly connected, or may mean that two structures are adjacent and indirectly connected. Indirect connection means that there is at least one intermediate structure (or intermediate layer, intermediate component, intermediate substrate, intermediate spacing) between two structures, the lower surface of a structure is adjacent or directly connected to the upper surface of the intermediate structure, and the upper surface of the other structure is adjacent or directly connected to the lower surface of the intermediate structure. The intermediate structure may be a single-layer or multi-layer physical structure or non-physical structure, which is not limited. In the disclosure, when a structure is disposed “on” another structure, it may mean that a structure is “directly” disposed on another structure, or a structure is “indirectly” disposed on another structure, that is, at least one structure is sandwiched between a structure and another structure.

The electrical connection or coupling described in the disclosure may refer to direct connection or indirect connection. In the case of a direct connection, terminals of two components on a circuit are directly connected or interconnected by a conductor segment. In the case of an indirect connection, there are switches, diodes, capacitors, inductors, other suitable components, or a combination of the above components between terminals of two components on a circuit, but are not limited thereto.

In the disclosure, the thickness, length and width may be measured by an optical microscope, and the thickness may be measured by a cross-sectional image in an electron microscope, but is not limited thereto. In addition, there may be some error between any two values or directions used for comparison. If a first value is equal to a second value, it implies that there may be an error of approximately 10% between the first value and the second value; if a first direction is perpendicular to a second direction, it implies that an angle between the first direction and the second direction may range from 80 to 100 degrees; and if a first direction is parallel to a second direction, it implies that an angle between the first direction and the second direction may range from 0 to 10 degrees.

In the disclosure, the embodiments described below may be combined and used without departing from the spirit and scope of the disclosure. For example, some features of one embodiment may be combined with some features of another embodiment to form another embodiment.

Exemplary embodiments of the disclosure are described in detail, and examples of the exemplary embodiments are shown in the accompanying drawings. Whenever possible, the same component symbols are used in the drawings and descriptions to indicate the same or similar parts.

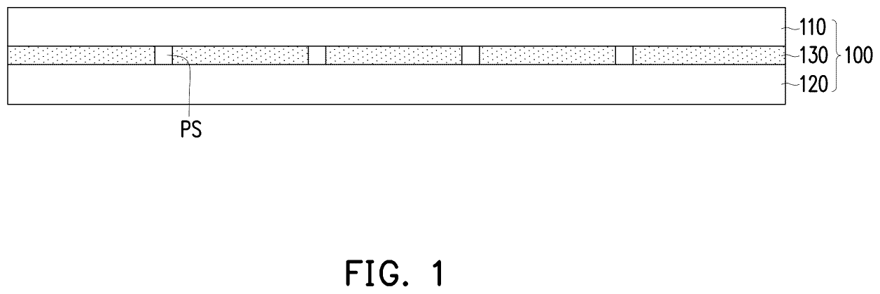

FIG. 1 is a schematic side view of an electronic device according to an embodiment of the disclosure. Referring to FIG. 1, an electronic device 100 includes a first substrate 110, a second substrate 120, and a medium 130, where the medium 130 is disposed between the first substrate 110 and the second substrate 120. The first substrate 110 is disposed opposite to the second substrate 120 and in a face-to-face manner. In at least some embodiments, the first substrate 110 and the second substrate 120 may be a rigid substrate or a flexible substrate, such as a plastic substrate or a glass substrate. For example, the first substrate 110 and the second substrate 120 may be made of materials respectively including glass, quartz, sapphire, ceramic, polycarbonate (PC), polyimide (PI), and polyethylene terephthalate (PET), liquid-crystal polymers (LCP), rubber, glass fiber, ceramic, other suitable substrate materials, or a combination thereof, but this is not limited thereto. The medium 130 may be made of a material such as a liquid crystal material, an electrowetting material, an electrophoretic material, an organic luminescent material, an inorganic luminescent material, etc., an organic light-emitting diode (OLED), a quantum dot (QD), a quantum dot light-emitting diode (QLED, QD-LED), a fluorescent material, a phosphor material, a light-emitting diode (LED), and a mini light-emitting diode (mini LED) or a micron light-emitting diode (micro LED), other suitable materials, or a combination of the foregoing, but this is not limited thereto. In some embodiments, the electronic device 100 further includes a spacer layer PS disposed between the first substrate 110 and the second substrate 120. The spacer layer PS may partition the first substrate 110 and the second substrate 120, and the spacer layer PS may have a plurality of columnar structures, but this is not limited thereto.

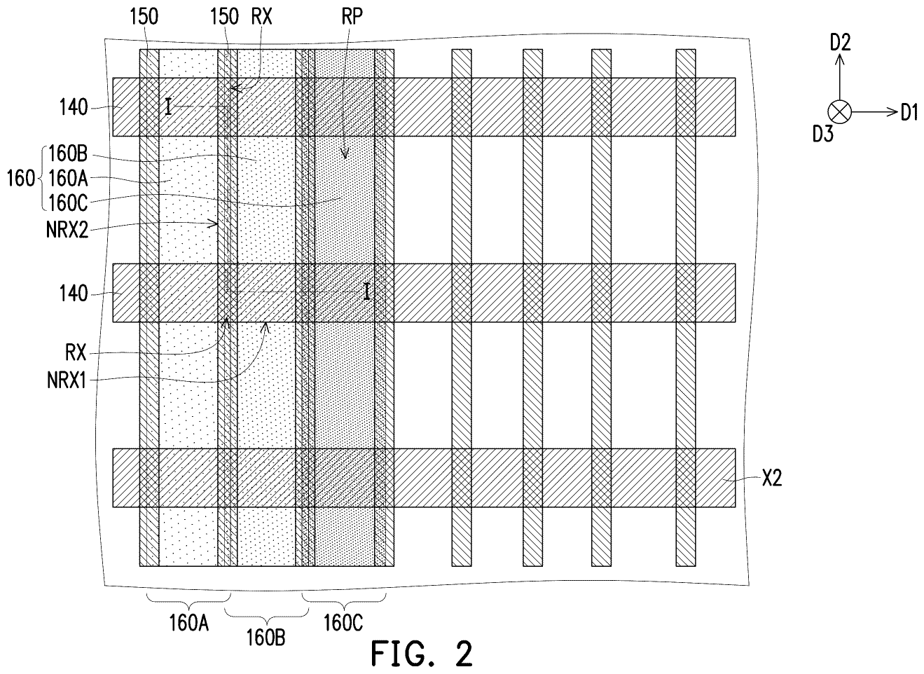

FIG. 2 is a schematic partial top view of an electronic device according to an embodiment of the disclosure. Referring to FIG. 1 and FIG. 2 simultaneously, an electronic device 100 further includes a plurality of first light-shielding strips 140, a plurality of second light-shielding strips 150, and a plurality of color filter patterns 160, where the color filter patterns 160 may be omitted in some embodiments. In the electronic device 100, a plurality of first light-shielding strips 140 may be disposed on a first substrate 110, and a plurality of second light-shielding strips 150 may be disposed between the first substrate 110 and a second substrate 120. The plurality of first light-shielding strips 140 may extend along a first direction D1, the plurality of second light-shielding strips 150 may extend along a second direction D2, and the second direction D2 intersects the first direction D1. In other words, the first direction D1 is different from the second direction D2. In some embodiments, the first direction D1 and the second direction D2 may be at a right angle or at an acute angle, but this is not limited thereto. In some embodiments, the second substrate 120 is, for example, an active component array substrate, that is, drive circuit correlation members such as a plurality of scanning lines, a plurality of data lines, and a plurality of active components and the like may be disposed on the second substrate 120. In this case, the first direction D1 has, for example, the same extending direction as the scanning line, and the second direction D2 has, for example, the same extending direction as the data line. In addition, the first light-shielding strips 140 and/or the second light-shielding strips 150 may block light, and light transmittance of the first light-shielding strip 140 and/or the second light-shielding strip 150 is, for example, less than 0.1% or less than 0.01%, or even is approximately 0%. The light transmittance is defined as a percentage of intensity of a light source after light having 100% intensity of the light source passes the first light-shielding strips 140 and/or the second light-shielding strips. In a third direction D3 (a normal direction of the first substrate 110), the second light-shielding strips 150 may selectively overlap the data lines to block the data lines (not shown), and the first light-shielding strips 140 may overlap the scanning line to block the scanning line (not shown). FIG. 2 does not limit the stacking order of the members, and a contour of the color filter pattern 160 is not shown for clarity of the drawing. In some embodiments, the boundary of the color filter pattern 160 may partially overlap one of the second light-shielding strips 150. Moreover, the adjacent two color filter patterns 160 may be adjacent to each other, and the boundary of the adjacent two color filter patterns 160 overlaps one of the second light-shielding strips 150.

In FIG. 2, the first light-shielding strip 140 may be an elongated structure extending along the first direction D1, and the second light-shielding strip 150 may be an elongated structure extending along the second direction D2. The plurality of first light-shielding strips 140 may be respectively interlaced with the plurality of second light-shielding strips 150, and a portion of the first light-shielding strips 140 overlapping a portion of the second light-shielding strips 150 in the third direction D3 is defined as an overlapping region RX. The other portion of the first light-shielding strip 140 outside the overlapping region RX is defined as a first non-overlapping region NRX1, and the other portion of the second light-shielding strip 150 outside the overlapping region RX is defined as a second non-overlapping region NRX2. The material of the first light-shielding strip 140 and/or the second light-shielding strip 150 may be selected from opaque materials such as black resin, ink, metal, and the like that can block light. The materials of both the first light-shielding strip 140 and the second light-shielding strip 150 may be identical to each other, but may be different from each other. The first light-shielding strips 140 may be a single-layer structure or a double-layer structure, and the second light-shielding strips 150 may be a single-layer structure or a two-layer structure, but this is not limited thereto. The first light-shielding strip 140 and the second light-shielding strip 150 construct a grid and substantially opaque black matrix.

The first light-shielding strip 140 and the second light-shielding strip 150 define a plurality of pixel regions RP, and the color filter patterns 160 are for example, at least partially disposed in the pixel regions RP. The pixel region RP is not shielded by the first light-shielding strip 140 and the second light-shielding strip 150. In other words, the pixel region RP does not overlap the first light-shielding strip 140 in the third direction D3, or does not overlap the second light-shielding strips 150, and therefore the pixel region RP is a light transmissive region. In addition, the color filter pattern 160 disposed in the pixel region RP may be used to determine colors of the plurality of pixel regions RP, but the disclosure is not limited thereto. In some embodiments, the color filter pattern 160 may be selectively not disposed in the pixel region RP. Materials of the color filter pattern 160 may include a color resist material or other suitable materials, but this is not limited thereto. Depending on different colors, the color filter pattern 160 may include a color filter pattern 160A, a color filter pattern 160B, and a color filter pattern 160C, where the color filter pattern 160A, the color filter pattern 160B, and the color filter pattern 160C may respectively, for example, appear in red, green and blue, but this is not limited thereto. In other embodiments, the color filter pattern 160 may include a color filter pattern of two colors, a color filter pattern of four colors, and the like. In some embodiments, the pixel region RP, the first light-shielding strip 140, and the second light-shielding strip 150 have an overall area, and the pixel region RP accounts for about 10% to 90% of the total area. In other words, the electronic device 100 may have an aperture ratio of 10% to 90%, but this is not limited thereto.

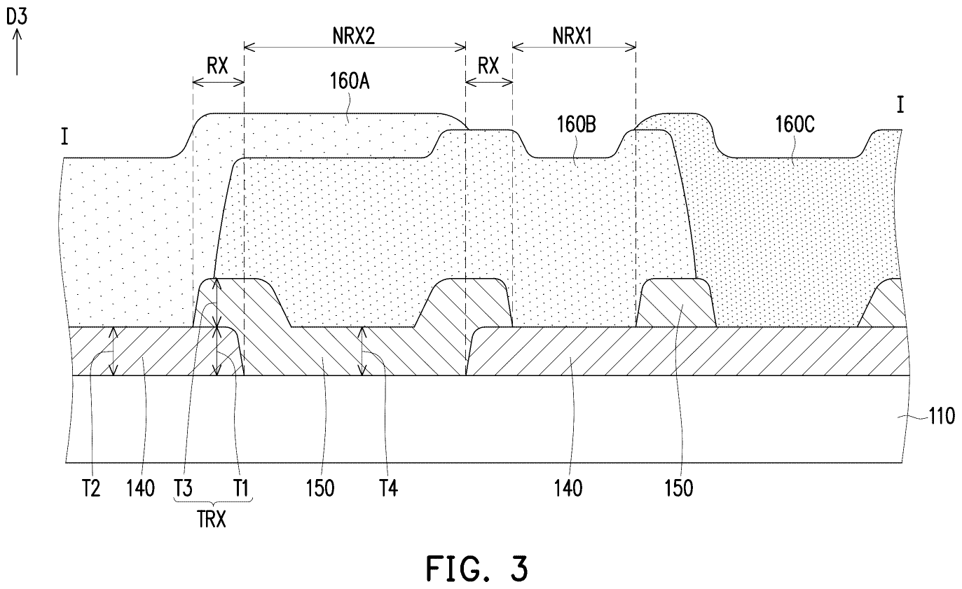

The stacking order of the first light-shielding strip 140, the second light-shielding strip 150, and the color filter pattern 160 may have a plurality of different designs. For example, FIG. 3 is a schematic cross-sectional view of an electronic device according to an embodiment of the disclosure, and FIG. 3 may be regarded as a schematic cross-sectional view of an embodiment of an electronic device taken along line I-I of FIG. 2. Referring to FIG. 2 and FIG. 3, in the present embodiment, the first light-shielding strips 140, the second light-shielding strips 150, and the color filter patterns 160A-160C are for example, sequentially stacked on the first substrate 110. The overlapping region RX has a total thickness TRX, a portion of the first light-shielding strips 140 in the total thickness TRX is defined to have a first thickness T1, and a portion of the second light-shielding strips 150 in the total thickness TRX is defined to have a third thickness T3. A of the first light-shielding strips 140 has a second thickness T2 in the first non-overlapping region NRX1. A of the second light-shielding strips 150 has a fourth thickness T4 in the second non-overlapping region NRX2. Because the second light-shielding strip 150 partially covers the first light-shielding strip 140, the first light-shielding strip 140 and/or the second light-shielding strip 150 near an edge of the overlapping region RX may have a thickness tapered region. It should be noted that, when the thickness is calculated, a cross-section in FIG. 2 is an example, and the second thickness T2 may be a maximum thickness of one of the first light-shielding strips 140 in the first non-overlapping region NRX1 in any cross section in the third direction D3. The fourth thickness T4 may be a maximum thickness of one of the second light-shielding strips 150 in the second non-overlapping region NRX2 in any cross section corresponding to a central region (as shown in FIG. 3) in the third direction D3, or the fourth thickness T4 may be a maximum thickness of one of the second light-shielding strips 150 in the second non-overlapping region NRX2 in a cross section taken in a direction perpendicular to a direction (the second direction D2) in which the second light-shielding strip 150 extends. The total thickness TRX may be a maximum thickness of the overlapping region RX in the third direction D3 in any cross section. In some embodiments, the total thickness TRX may be different from the fourth thickness T4, and/or the total thickness TRX may be different than the second thickness T2. For example, the total thickness TRX may be greater than the second thickness T2, and the total thickness TRX may be greater than the fourth thickness T4. In some embodiments, the ratio of the total thickness TRX to the second thickness T2 (or the fourth thickness T4) may be any value in ranges such as 1.1 to 1.5, 1.1 to 1.8, 1.1 to 2, 1.2 to 1.5, 1.2 to 1.8, 1.2 to 2, 1.5 to 1.8, 1.5 to 2, 1.8 to 2, and so on. In some embodiments, a maximum thickness of a corresponding member in the third direction D3 may be measured in an electron microscope image of any section plane as the thickness described herein. In addition, because the third thickness T3 is the thickness measured by the portion of the second light-shielding strip 150 covering the first light-shielding strip 140, the fourth thickness T4 and the third thickness T3 may be different. However, in some embodiments, the fourth thickness T4 and the third thickness T3 may be the same.

The first light-shielding strips 140 and the second light-shielding strips 150 may be manufactured in different manufacturing steps, and the first light-shielding strips 140 and the second light-shielding strips 150 are in contact with each other at the overlapping region RX, and a physical boundary may exist therebetween. When the first light-shielding strip 140 and the second light-shielding strip 150 are made of different materials, the physical boundary between the two may be defined according to the difference in properties of different materials. However, when the first light-shielding strip 140 and the second light-shielding strip 150 are made of the same material or different materials, the physical boundary between the two may be less apparent. In some embodiments, the first light-shielding strip 140 and the second light-shielding strip 150 may have no obvious physical boundary, and therefore the first thickness T1 and the second thickness T2 are not easily measured separately. In this case, the overall thickness that is of the light-shielding pattern measured in the overlapping region RX and that is in the overlapping region RX may be used as the total thickness TRX.

The stacking order of the first light-shielding strip 140, the second light-shielding strip 150, and the color filter patterns 160A-160C in FIG. 3 is used as an example for description. In other embodiments, the first light-shielding strip 140, the second light-shielding strip 150, and the color filter patterns 160A-160C may be stacked according to other stacking orders, and other films or members may be additionally disposed between the first light-shielding strip 140, the second light-shielding strip 150, and any two of the color filter patterns 160A to 160C. In other words, the first light-shielding strips 140 and the second light-shielding strips 150 do not necessarily contact each other in the overlapping region RX, and the color filter patterns 160A-160C do not necessarily contact at least one of the first light-shielding strips 140 and the second light-shielding strips 150. In addition, the color filter patterns 160A to 160C may also be made by using different manufacturing steps. Therefore, the adjacent two of the color filter patterns 160A to 160C may also overlap each other. For example, the color filter pattern 160B in FIG. 3 is for example, made earlier than the color filter pattern 160A, and also earlier than the color filter pattern 160C. Therefore, at the boundary between the color filter pattern 160A and the color filter pattern 160B of FIG. 3, the color filter pattern 160A may be stacked on the color filter pattern 160B. In addition, at the boundary between the color filter pattern 160B and the color filter pattern 160C, the color filter pattern 160C may be stacked on the color filter pattern 160B. However, in other embodiments, the color filter patterns 160A-160C may have other stacking orders. In some embodiments, the color filter patterns 160A-160C may be made of the same or similar materials, so that the physical boundaries between each other may be less obvious.

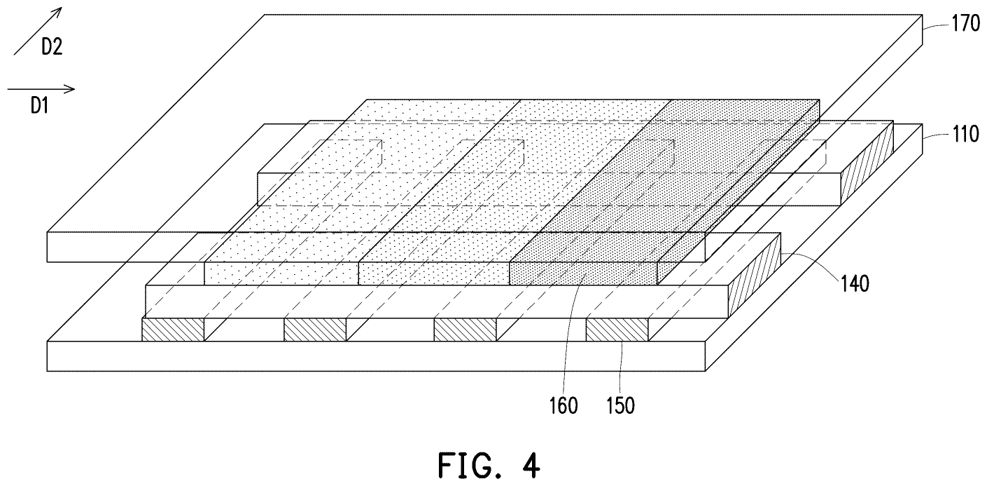

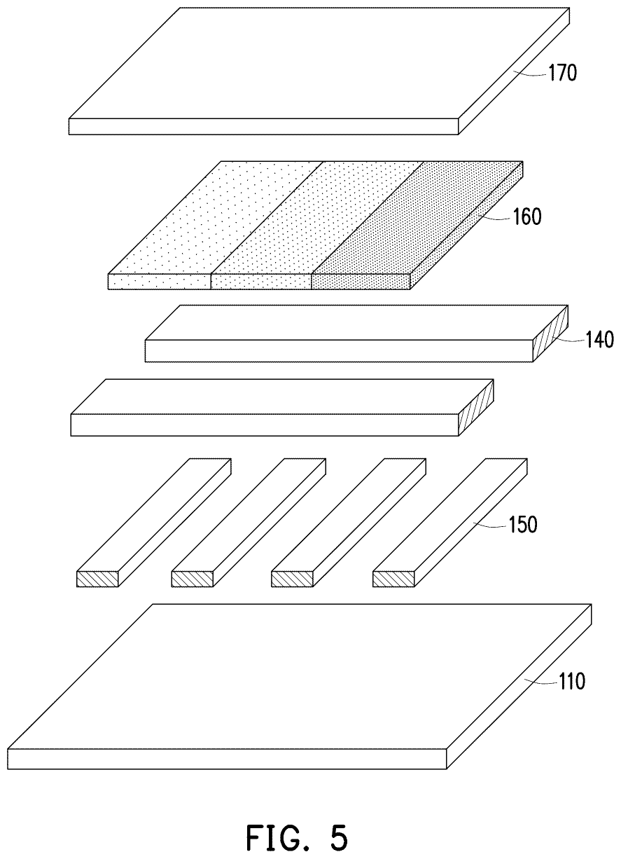

FIG. 4 is a schematic diagram of a member between a first substrate 110 and a medium 130 (not shown in FIG. 4) in an electronic device according to another embodiment of the disclosure, and FIG. 5 is a schematic diagram of a stacking order of members in FIG. 4. The members described in the present embodiment may be applied to the electronic device 100 of FIG. 1, and therefore a same component symbol is used to denote same or similar parts in the drawings and the description. Referring to FIG. 4 and FIG. 5, a plurality of second light-shielding strips 150, a plurality of first light-shielding strips 140, and a plurality of color filter patterns 160 of the present embodiment are for example, sequentially stacked on a first substrate 110. In addition, a planarization layer 170 may be selectively further disposed on the first substrate 110, and the planarization layer 170 covers the first light-shielding strip 140, the second light-shielding strip 150, and the color filter pattern 160. The material of the planarization layer 170 may include materials such as perfluoroalkoxy polymer resin (PFA), a polymer film on array (PFA), fluoroelastomers, or the like. Although a plurality of members (the first light-shielding strip 140, the second light-shielding strip 150, and the color filter pattern 160) with different patterns exist between the planarization layer 170 and the first substrate 110, because a thickness of the planarization layer 170 is substantially the same as a thickness of the color filter pattern 160 or a total thickness TRX, the planarization layer 170 may provide a relatively flat surface on a side away from the first substrate 110. In some embodiments, a ratio of the thickness of the planarization layer 170 to a thickness of an upper color filter pattern 160 or the total thickness TRX may be any value in the range of 0.8 to 2, 1.0 to 1.5, and the like. It is mentioned herein that the ratio in the range of A to B may be understood as a relationship of A≤ratio≤B.

When the embodiment of FIG. 4 is applied to the electronic device of FIG. 1, a structure of FIG. 4 may be flipped upside down and then paired with a second substrate 120. In other words, when the structure of FIG. 4 is applied to the electronic device of FIG. 1, the first light-shielding strip 140, the second light-shielding strip 150, and the color filter pattern 160 are located between the first substrate 110 and the second substrate 120. It may be learned from FIG. 1, FIG. 4, and FIG. 5 that the second light-shielding strip 150 is disposed on the first substrate 110, located between the first substrate 110 and the second substrate 120, and may be located between the first substrate 110 and the medium 130. The first light-shielding strips 140 and the color filter patterns 160 are disposed between the second light-shielding strip 150 and the second substrate 120, and in particular, the first light-shielding strip 140 may be located between the second light-shielding strip 150 and the medium 130, and the color filter pattern 160 may also be located between the first light-shielding strip 140 and the medium 130. The planarization layer 170 is disposed between at least one of the first light-shielding strip 140 and the second light-shielding strip 150 and the second substrate 120, and may be located between the first light-shielding strip 140 and the medium 130. In other words, the first light-shielding strip 140, the second light-shielding strip 150, and the color filter pattern 160 are all disposed between the planarization layer 170 and the first substrate 110.

In some embodiments, if the second light-shielding strip 150 is closer to a user than the first light-shielding strip 140, the second light-shielding strip 150 may select a material having a lower light reflectance to improve quality of the electronic device 100, but this is not limited thereto.

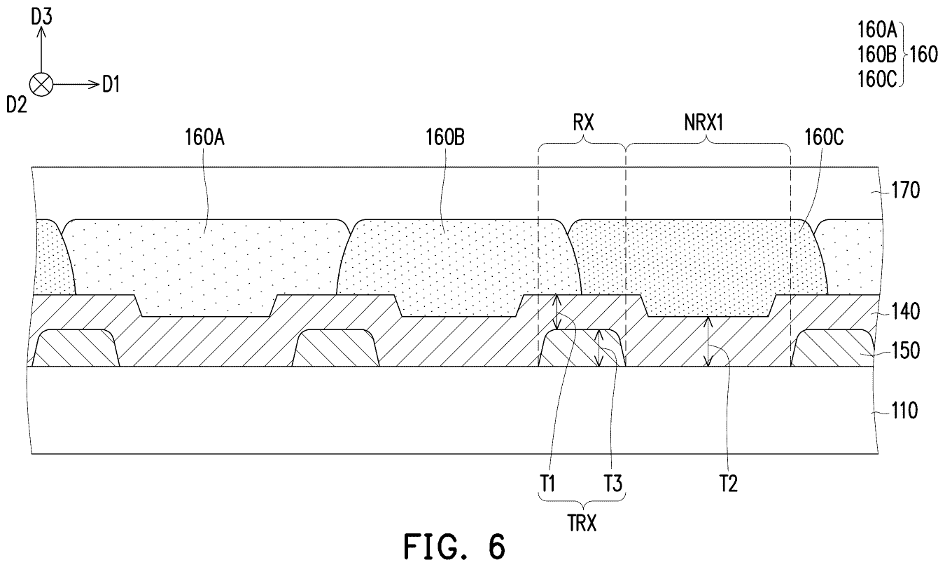

FIG. 6 is a schematic partial cross-sectional view of a member of FIG. 4. The cross-sectional cutting direction of the cross-sectional view of FIG. 6 is, for example, taken along one of the first light-shielding strips 140 in FIG. 2. Referring to FIG. 6, a portion RX of the first light-shielding strips 140 overlapping the second light-shielding strips 150 in a third direction D3 is defined as an overlapping region RX. The overlapping region RX has a total thickness TRX, a portion of the first light-shielding strips 140 in the total thickness TRX is defined to have a first thickness T1, and a portion of the second light-shielding strips 150 in the total thickness TRX is defined to have a third thickness T3. One of the first light-shielding strips 140 has a second thickness T2 in the first non-overlapping region NRX1. One of the second light-shielding strips 150 has a fourth thickness T4 in the second non-overlapping region NRX2. Because the first light-shielding strip 140 partially covers the second light-shielding strip 150, the first light-shielding strip 140 and/or the second light-shielding strip 150 near an edge of the overlapping region RX may have a thickness tapered region. When the thickness is calculated, a cross section in FIG. 6 is an example, and the second thickness T2 may be a maximum thickness of one of the first light-shielding strips 140 in the first non-overlapping region NRX1 in any cross section in the third direction D3 corresponding to a central region (as shown in FIG. 6) in the third direction D3, or the second thickness T4 may be a maximum thickness of one of the second light-shielding strips 150 in the second non-overlapping region NRX2 in a cross section taken in a direction perpendicular to a direction (the first direction D1) in which the first light-shielding strip 140 extends. The total thickness TRX may be a maximum thickness of the overlapping region RX in the third direction D3 in any cross section. The total thickness TRX may be a sum of the first thickness T1 and the third thickness T3. The total thickness TRX may be greater than the second thickness T2. According to the manufacturing sequence, the first light-shielding strip 140 is stacked on the second light-shielding strip 150, so the second thickness T2 may be different from the first thickness T1. For example, the first thickness T1 is less than the second thickness T2, but this is not limited thereto. It should be noted that for the definition of the thickness in FIG. 6, reference may be made to the definition of the thickness in FIG. 3, and the descriptions thereof are omitted herein.

In the present embodiment, the color filter pattern 160 may be divided into color filter patterns 160A-160C, which respectively present different colors. The color filter pattern 160B is made earlier than the color filter pattern 160A, and also earlier than the color filter pattern 160C. Therefore, at the boundary between the color filter pattern 160A and the color filter pattern 160B of FIG. 6, the color filter pattern 160A may be stacked on the color filter pattern 160B. In addition, at the boundary between the color filter pattern 160B and the color filter pattern 160C, the color filter pattern 160C may be stacked on the color filter pattern 160B. However, in other embodiments, the color filter patterns 160A-160C may have other stacking orders. In other embodiments, the adjacent two of the color filter patterns 160A to 160C may be spaced apart from each other without being in contact with each other. In addition, although three color types of the color filter pattern 160 are used as an example for description, this is not limited thereto. In some embodiments, the color filter patterns 160A-160C may be made of the same or similar materials, so that the physical boundaries between each other may be less obvious.

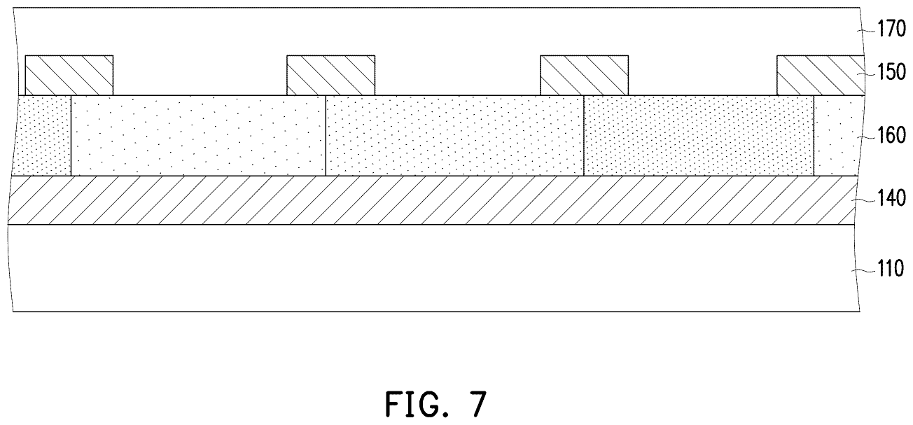

FIG. 7 is a schematic partial cross-sectional view of a member between a first substrate 110 and a medium 130 (not shown in FIG. 7) in an electronic device according to another embodiment of the disclosure. The cross-sectional cutting direction of the cross-sectional view of FIG. 7 is, for example, taken along one of the first light-shielding strips 140 in FIG. 2. The present embodiment is similar to the embodiment of FIG. 6, and the constituent members of the two embodiments are substantially identical, but the stacking order of the members is different. In the present embodiment, the first light-shielding strip 140, the color filter pattern 160, the second light-shielding strip 150, and the planarization layer 170 are sequentially stacked on the first substrate 110. The first light-shielding strips 140 and the second light-shielding strips 150 are respectively disposed on both sides of the color filter pattern 160, and both contact the color filter pattern 160.

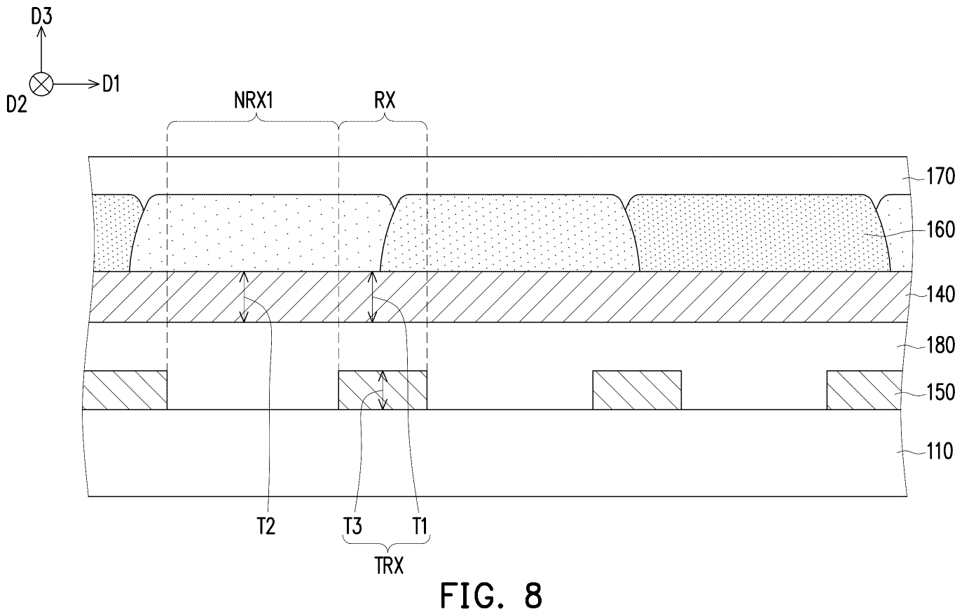

FIG. 8 is a schematic partial cross-sectional view of a member between a first substrate 110 and a medium 130 (not shown in FIG. 8) in an electronic device according to yet another embodiment of the disclosure. The cross-sectional cutting direction of the cross-sectional view of FIG. 8 is, for example, taken along one of the first light-shielding strips 140 in FIG. 2. Referring FIG. 8, in the present embodiment, a second light-shielding strip 150, a first light-shielding strip 140, a color filter patterns 160, and a planarization layer 170 are sequentially stacked on the first substrate 110, and another planarization layer 180 is further disposed between the first light-shielding strip 140 and the second light-shielding strip 150. For the stacking order of the first light-shielding strip 140, the second light-shielding strip 150, and the color filter pattern 160 of the present embodiment, reference may be made to the embodiments of FIG. 4 to FIG. 6, and the descriptions thereof are omitted herein. A difference between the present embodiment and the embodiment of FIG. 4 mainly lies in that the present embodiment further includes a planarization layer 180. The planarization layer 180 and the planarization layer 170 are for example, made of organic materials including materials such as perfluoroalkoxy polymer resin (PFA), fluoroelastomers, or the like. The planarization layer 180 and the planarization layer 170 may be made of different materials or may be made of the same material. The planarization layer 180 and the planarization layer 170 have, for example, a thicker thickness relative to the other layers to provide planarization. In other words, although there are other patterned members (for example, the second light-shielding strip 150) between the planarization layer 180 and the first substrate 110, the planarization layer 180 is disposed to provide a relatively flat surface on which the first light-shielding strip 140 is disposed. Similarly, although a plurality of members (the first light-shielding strip 140, the color filter pattern 160, etc.) with different patterns exists between the planarization layer 170 and the planarization layer 180, the planarization layer 170 may be disposed away from one side of the first substrate 110 to provide a relatively flat surface.

The second light-shielding strip 150 overlaps the first light-shielding strip 140, so that an overlapping region RX is defined. The overlapping region RX has a total thickness TRX, a portion of the first light-shielding strips 140 in the total thickness TRX is defined to have a first thickness T1, and a portion of the second light-shielding strips 150 in the total thickness TRX is defined to have a third thickness T3. One of the first light-shielding strips 140 has a second thickness T2 in the first non-overlapping region NRX1. In some embodiments, the total thickness TRX may be a sum of the first thickness T1 and the third thickness T3, and the total thickness TRX may be greater than the second thickness T2. In addition, in the cross-sectional structure (not shown in FIG. 8) of the other direction, the second light-shielding strip 150 in the second non-overlapping region NRX2 (not shown in FIG. 8) outside the overlapping region RX has a fourth thickness T4, and the fourth thickness may also be less than the total thickness TRX. In the present embodiment, the first light-shielding strip 140 is disposed on the planarization layer 180 and may have a relatively uniform thickness, and therefore the second thickness T2 and the first thickness T1 may be equal to each other, but may also be slightly different. In addition, the second light-shielding strip 150 is disposed on the first substrate 110, and therefore the third thickness T3 and the fourth thickness (not shown) may also be equal to each other, but may also be slightly different.

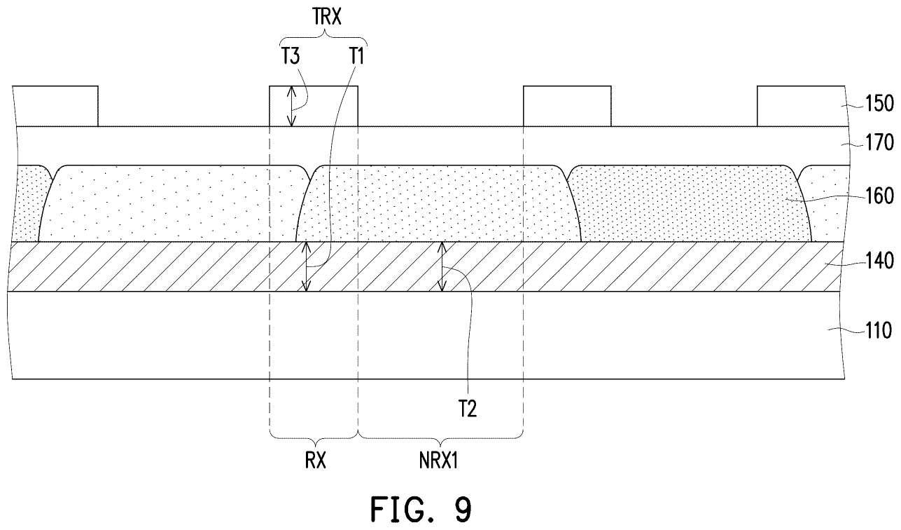

FIG. 9 is a schematic partial cross-sectional view of a member between a first substrate 110 and a medium 130 (not shown in FIG. 9) in an electronic device according to a further embodiment of the disclosure. The cross-sectional cutting direction of the cross-sectional view of FIG. 9 is, for example, taken along one of the first light-shielding strips 140 in FIG. 2. Referring to FIG. 9, in the present embodiment, the first light-shielding strip 140, a color filter pattern 160, a planarization layer 170, and a second light-shielding strip 150 are sequentially stacked on the first substrate 110. In such a stacking order, the color filter pattern 160 is located between the first light-shielding strip 140 and the second light-shielding strip 150, and at least the color filter pattern 160 and the planarization layer 170 exist between the first light-shielding strip 140 and the second light-shielding strip 150. The second light-shielding strip 150 overlaps the first light-shielding strip 140, so that an overlapping region RX is defined. The overlapping region RX has a total thickness TRX, a portion of the first light-shielding strips 140 in the total thickness TRX is defined to have a first thickness T1, and a portion of the second light-shielding strips 150 in the total thickness TRX is defined to have a third thickness T3. One of the first light-shielding strips 140 has a second thickness T2 in the first non-overlapping region NRX1. The total thickness TRX may be a sum of the first thickness T1 and the third thickness T3, and the total thickness TRX may be greater than the second thickness T2. In addition, in the cross-sectional structure (not shown in FIG. 9) of the other direction, one of the second light-shielding strips 150 in the second non-overlapping region (not shown in FIG. 9) may have a fourth thickness (not shown in FIG. 9), and the fourth thickness (not shown in FIG. 9) may be less than the total thickness TRX. In the present embodiment, materials of the first light-shielding strip 140 and the second light-shielding strip 150 may include light-shielding materials such as black resin, ink, metal, and the like. In some embodiments, the first light-shielding strip 140 is closer to a user than the second light-shielding strip 150, and therefore the first light-shielding strip 140 may select a material having a lower light reflectance to improve quality of the electronic device 100. In addition, the second light-shielding strip 150 is farther away from the user, and the second light-shielding strip 150 is disposed to help block leaky light from the oblique viewing angle and help improve the quality of the electronic device 100.

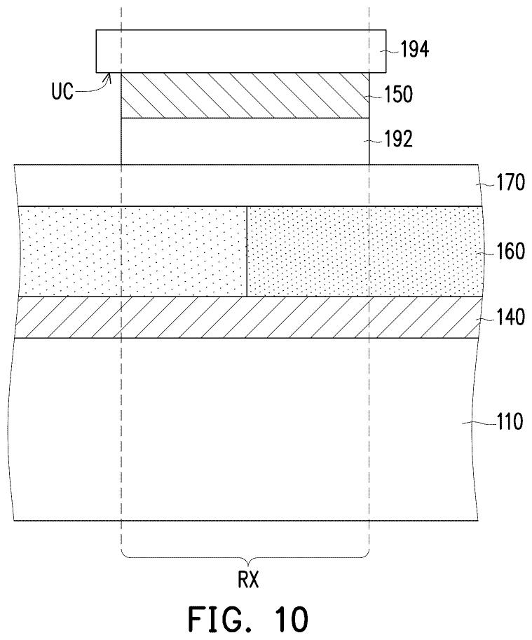

FIG. 10 is a schematic partial cross-sectional view of a member between a first substrate 110 and a medium 130 (not shown) in an electronic device according to a further embodiment of the disclosure. The cross-sectional cutting direction of the cross-sectional view of FIG. 10 is, for example, taken along one of the first light-shielding strips 140 in FIG. 2. Referring to FIG. 10, the present embodiment is similar to the embodiment of FIG. 9, where the first light-shielding strip 140, a color filter pattern 160, a planarization layer 170, and a second light-shielding strip 150 are sequentially stacked on the first substrate 110. In an embodiment, an interface layer 192 is disposed between the second light-shielding strip 150 and the planarization layer 170. In another embodiment, an interface layer 192 and an interface layer 194 may be respectively disposed on two opposite sides of the second light-shielding strip 150. The interface layer 192 is disposed between the second light-shielding strip 150 and the planarization layer 170, and the second light-shielding strip 150 is disposed between the interface layer 192 and the interface layer 194. In other words, the interface layer 192, the second light-shielding strip 150, and the interface layer 194 are sequentially stacked on the planarization layer 170. The interface layer 192 is disposed between the second light-shielding strip 150 and the first substrate 110. The interface layer 192 is disposed between the second light-shielding strip 150 and the first light-shielding strip 140. The interface layer 192 is disposed between the second light-shielding strip 150 and a color filter pattern 160.

In the present embodiment, the interface layer 192 and/or the interface layer 194 may have a contour corresponding to the second light-shielding strip 150. For example, the interface layer 192, the second light-shielding strip 150, and/or the interface layer 194 may be patterned using the same photomask to have an approximate structure contour (for example, an elongated contour of the second light-shielding strip 150 in FIG. 2). For example, in the manufacturing process, the inorganic material, the metal material, and/or another inorganic material may be sequentially formed on the planarization layer 170 or the color filter pattern 160 through deposition, coating, printing, or the like. Next, the stack layer of the inorganic material, the metal material, and another inorganic material is patterned using the same photomask patterning to form the interface layer 192, the second light-shielding strip 150, and another interface layer 194. The patterning method may include a lithography etching process. Upon completion of etching, the interface layer 192 and the second light-shielding strip 150 may be retracted relative to the interface layer 194 to form an undercut structure UC. In other embodiments, the interface layer 192, the second light-shielding strip 150, and the interface layer 194 may be respectively patterned using different steps. Therefore, the undercut structure UC may also not exist.

In the present embodiment, the second light-shielding strip 150 is made of materials including metal such as molybdenum, aluminum, chromium, or the like, or other suitable metal materials, or a combination of the foregoing, but this is not limited thereto. In some embodiments, the material of the second light-shielding strip 150 may be different from the material of the first light-shielding strip 140. The interface layer 192 and/or the interface layer 194 may be made of materials including an inorganic material such as silicon nitride, silicon oxide, silicon oxynitride, indium tin oxide (ITO), or other inorganic materials, or other suitable transparent materials, but this is not limited thereto. Similar to the foregoing embodiments, the planarization layer 170 may be made of materials including an organic material, and the second light-shielding strip 150 and the interface layer 192 may include an inorganic material. The interface layer 192 is disposed between the second light-shielding strip 150 and the planarization layer 170, helping improve stability of the second light-shielding strip 150. In addition, the interface layer 194 covers the second light-shielding strip 150, which also helps increase a protective effect (for example, increase the resistance to water and oxygen) of the second light-shielding strip 150. The interface layer 192 is disposed between the second light-shielding strip 150 and a color filter pattern 160. In addition, in other embodiments, the interface layer 192 and the second light-shielding strip 150 may be disposed on the second substrate 120 in the electronic device 100 of FIG. 1.

Further, when the present embodiment is applied to the electronic device 100 of FIG. 1, a spacer layer PS of FIG. 1 may be disposed on the interface layer 194 without contacting the second light-shielding layer 150, and the interface layer 194 is disposed between the spacer layer PS and the second light-shielding layer 150, which can help improve adhesion of the spacer layer PS. In addition, when the interface layer 194 is made of indium tin oxide (ITO) or other oxides of conductive properties, the interface layer 194 may not be patterned, and an entire surface is covered on the first substrate 110. In this case, the interface layer 194 may be used as a counter electrode in the electronic device 100.

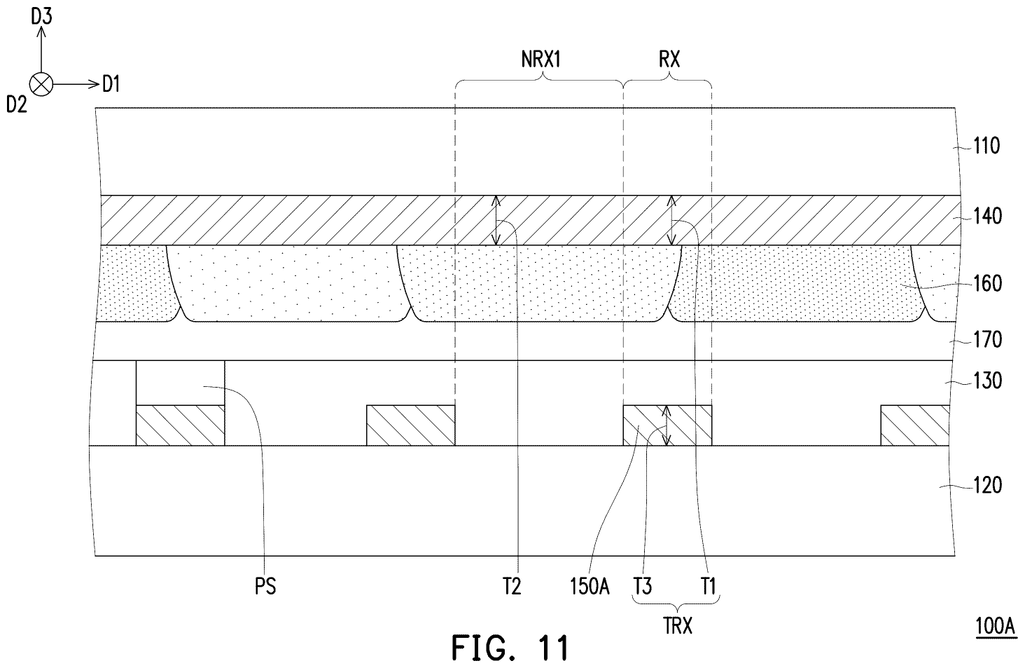

FIG. 11 is a schematic cross-sectional view of an electronic device according to still another embodiment of the disclosure. Referring to FIG. 11, the electronic device 100A includes a first substrate 110, a second substrate 120, a medium 130, a first light-shielding strip 140, a second light-shielding strip 150A, a color filter pattern 160, and a planarization layer 170. In the present embodiment, the stacking order of the first substrate 110, the first light-shielding strip 140, the color filter pattern 160, and the planarization layer 170 and a correspondence between each other are substantially similar to the embodiment of FIG. 9. Therefore, for specific structures of the first substrate 110, the first light-shielding strip 140, the color light pattern 160, and the planarization layer 170, reference may be made to the foregoing embodiment, and the descriptions thereof are omitted herein. In addition, the second light-shielding strips 150A are for example, disposed on the second substrate 120 in the present embodiment. As shown in FIG. 11, the second light-shielding strips 150A are located between the second substrate 120 and the first light-shielding strip 140, and is specifically located between the second substrate 120 and the medium 130. In addition, the electronic device 100A further includes a spacer layer PS, and the space layer PS is located between the first substrate 110 and the second light-shielding strips 150A.

In the present embodiment, the first light-shielding strips 140 are disposed on the first substrate 110, the second light-shielding strips 150A are disposed on the second substrate 120, and the first light-shielding strip 140 and the second light-shielding strips 150A are respectively located on opposite sides of the medium 130. The second light-shielding strips 150A may be made of materials including metal such as molybdenum, aluminum, chromium, or the like, or other suitable metal materials, or a combination of the foregoing, but this is not limited thereto. In some embodiments, the material of the second light-shielding strips 150A may be different from the material of the first light-shielding strips 140. The second light-shielding strips 150 overlap the first light-shielding strips 140, so that an overlapping region RX is defined. The overlapping region RX has a total thickness TRX, a portion of the first light-shielding strips 140 in the total thickness TRX is defined to have a first thickness T1, and a portion of the second light-shielding strips 150 in the total thickness TRX is defined to have a third thickness T3. One of the first light-shielding strips 140 has a second thickness T2 in the first non-overlapping region NRX1. The total thickness TRX may be a sum of the first thickness T1 and the third thickness T3, and the total thickness TRX may be greater than the second thickness T2.

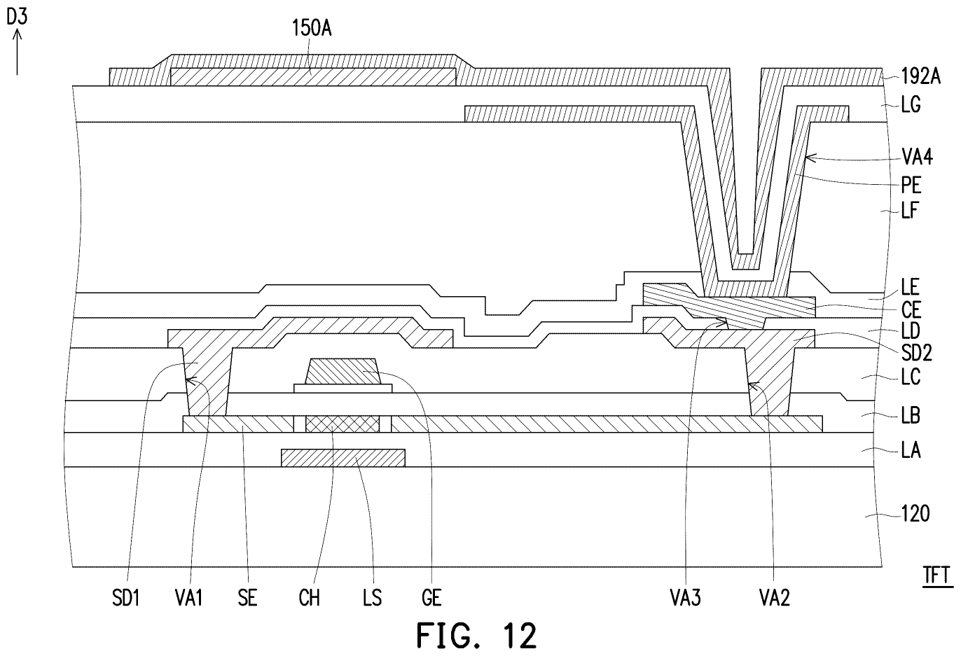

In the present embodiment, the first substrate 110 and members disposed thereon may constitute a color filter substrate, and the second substrate 120 and the members formed thereon may constitute an active component array substrate. Specifically, in addition to the second light-shielding strips 150A, other members are further disposed on the second substrate 120. For example, FIG. 12 is a schematic cross-sectional view of an active component array substrate according to an embodiment of the disclosure. The active component array substrate TFT of FIG. 12 includes a second substrate 120, a light-shielding layer LS, a semiconductor layer SE, a gate GE, a first source/drain SD1, a second source/drain SD2, a connection electrode CE, a pixel electrode PE, a second light-shielding strip 150A, and an interface layer 192A. In addition, the active component array substrate TFT further includes a plurality of insulating layers LA-LG disposed on the second substrate 120.

It may be learned from FIG. 12 that the light-shielding layer LS is disposed on the second substrate 120, and the insulating layer LA covers the light-shielding layer LS. In other words, the light-shielding layer LS is located between the second substrate 120 and the insulating layer LA. The semiconductor layer SE is disposed on the insulating layer LA, and the semiconductor layer SE may have a channel region CH. The insulating layer LB covers the semiconductor layer SE, and the gate electrode GE is disposed on the insulating layer LB. Both the gate GE and the light-shielding layer LS overlap the channel region CH in a third direction, where a signal on the gate GE may control carrier (electron or hole) mobility of the channel region CH, and the light-shielding layer LS may reduce light exposure to the channel region CH to reduce the chance of occurrence of a light leakage current in the channel region CH. The insulating layer LC covers the gate GE, and the first source/drain SD1 and the second source/drain SD2 are both disposed on the insulating layer LC. The first source/drain SD1 may be in contact with and electrically connected to the semiconductor layer SE through a via VA1, and the second source/drain SD2 may be in contact with and electrically connected to the semiconductor layer SE through a via VA2. The insulating layer LC covers the first source/drain SD1 and the second source/drain SD2, and the connection electrode CE is disposed on the insulating layer LD. The connection electrode CE may be in contact with and electrically connected to the second source/drain SD2 through a via VA3. The insulating layer LE covers the connection electrode CE, and the insulating layer LF covers the insulating layer LE, where the insulating layer LF may be thicker than the insulating layer LE to provide a planarization effect. The pixel electrode PE is disposed on the insulating layer LF, and is in contact with and electrically connected to the connection electrode CE through a via VA4. The insulating layer LG covers the pixel electrode PE, and the second light-shielding strip 150A is disposed on the insulating layer LG. The interface layer 192A is disposed on the insulating layer LG and covers the second light-shielding strip 150A. In other words, the second light-shielding strip 150A is located between the interface layer 192A and the insulating layer LG.

When the active component array substrate TFT in FIG. 12 is applied to the electronic device 100A in FIG. 11, both the interface layer 192A and the spacer layer PS may be located between the first light-shielding strip 140 and the second light-shielding strip 150A, the spacer layer PS may be at least partially disposed at an intersection (that is, an overlapping region RX) of the first light-shielding strip 140 and the second light-shielding strip 150A, and the interface layer 192A is located between the second light-shielding strip 150A and the spacer layer PS. In this way, the spacer layer PS does not contact the second light-shielding strip 150A. The second light-shielding strip 150A may be made of materials including metal such as molybdenum, aluminum, and chromium, etc., or other suitable metallic materials, or a combination of the foregoing, which is not limited thereto. In some embodiments, the material of the second light-shielding strips 150A may be different from the material of the first light-shielding strips 140. The interface layer 192A is disposed between the spacer layer PS and the second light-shielding strip 150A, which can help improve adhesion of the spacer layer PS. In addition, the interface layer 192A may be made of indium tin oxide or other transparent conducting material. In other words, the interface layer 192A may be a transparent conducting layer and may be electrically connected to a shared signal and used as a shared electrode in the active component array substrate TFT. In this case, the interface layer 192A may have a plurality of slits (not shown) to achieve the design that a fringe field drives a pixel. In other embodiments, the interface layer 192A may be, for example, silicon nitride, silicon oxide, silicon oxynitride, or other suitable transparent materials, which is not limited thereto.

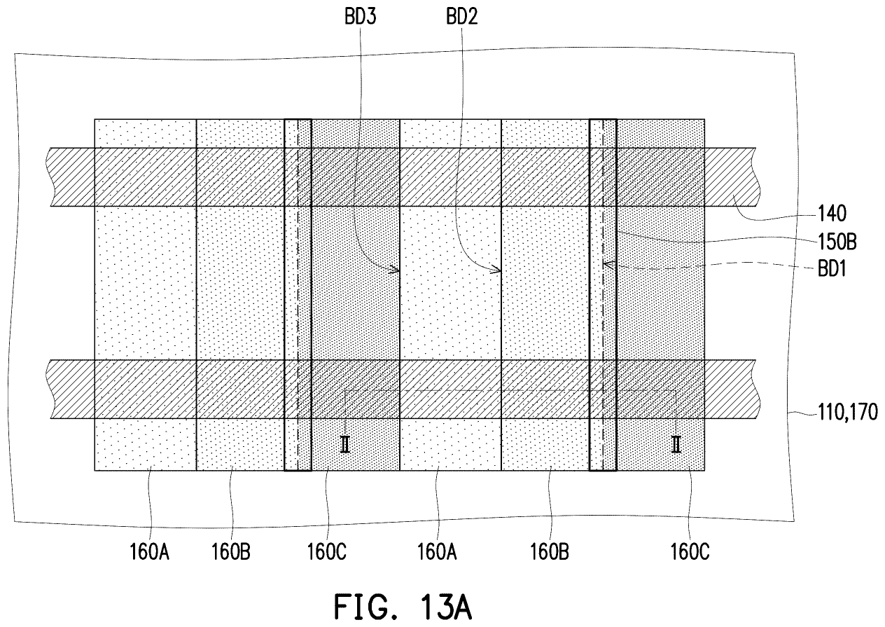

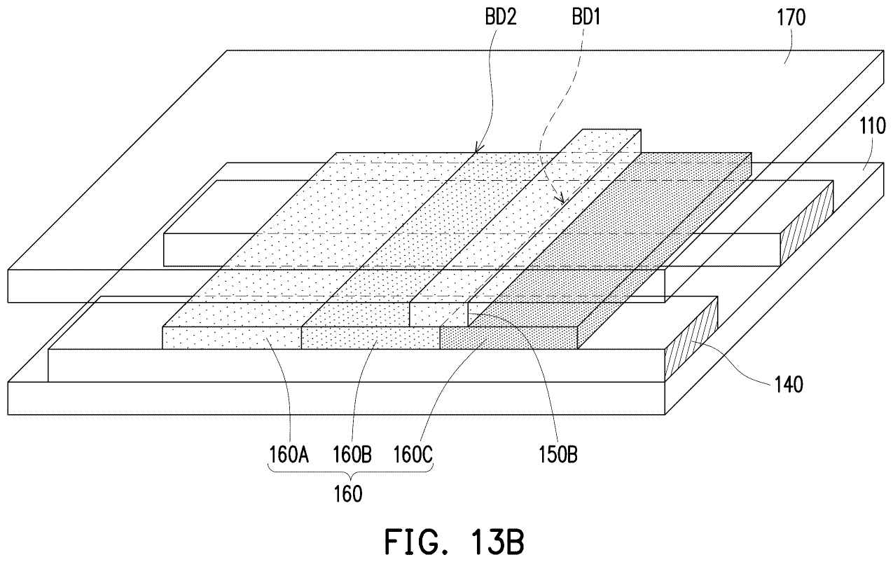

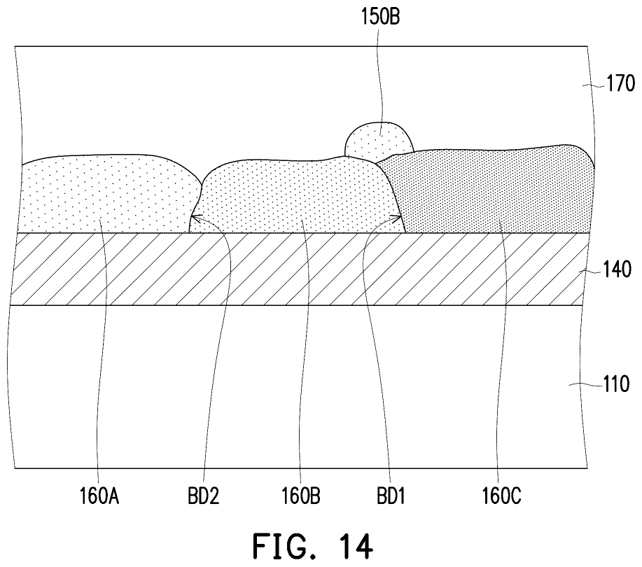

FIG. 13A is a partially schematic top view of a component between a first substrate 110 and a medium 130 (not shown in FIG. 13A) in an electronic device according to still another embodiment of the disclosure. FIG. 13B is a partially schematic perspective view of a structure of FIG. 13A taken along line II-II, and FIG. 14 is a schematic cross-sectional view of a structure of FIG. 13A taken along line II-II. Referring to FIG. 13A, FIG. 13B, and FIG. 14, in the present embodiment, a first light-shielding strip 140, a color filter pattern 160, a second light-shielding strip 150B, and a planarization layer 170 are sequentially stacked on the first substrate 110. The color filter pattern 160 may be divided into a color filter pattern 160A, a color filter pattern 160B, and a color filter pattern 160C depending on colors. The second light-shielding strip 150B may be disposed at a boundary BD1 between the color filter pattern 160B and the color filter pattern 160C. In other words, the second light-shielding strip 150B may not be disposed at a boundary BD2 between the first color filter pattern 160A and the second color filter pattern 160B and at a boundary BD3 between the first color filter pattern 160A and the color filter pattern 160C. The light-shielding strip 140 and/or the second light-shielding strip 150B may be made of a material including a black matrix layer, a metallic material, or other appropriate materials with low light transmittance, or a combination of the foregoing. The material for manufacturing the second light-shielding strip 150B herein may include a black matrix layer or a color resist. In addition, light transmittance of at least one of the first light-shielding strip 140 and the second light-shielding strip 150B may be less than 0.1% or less than 0.01%, or even approximately 0%.

In the present embodiment, the second light-shielding strip 150B may be made of a color resist that is the same as the material of the color filter pattern 160A. For example, the color filter pattern 160A may be manufactured after the color filter pattern 160B and the color filter pattern 160C are manufactured, and the second light-shielding strip 150B may be manufactured while the color filter layer 160A is being manufactured, thereby saving a number of processes. In some embodiments, the color filter pattern 160A may be a blue filter pattern, one of the color filter pattern 160B and the color filter pattern 160C is a red filter pattern, and the other is a green filter pattern. In color space, luminance/luma of blue is lower than that of red and green. Therefore, the second light-shielding strip 150B made of the blue filter pattern may provide a desired light-shielding effect. However, the foregoing selected colors are used as an example for description, which is not limited thereto. Although a light-shielding strip is not additionally disposed at the boundary BD2 between the color filter pattern 160A and the color filter pattern 160B and the boundary BD3 between the color filter pattern 160A and the color filter pattern 160C, in other embodiments, the second light-shielding strip 150 or 150A described in the foregoing embodiment may be selectively disposed at the boundary BD2 and the boundary BD3.

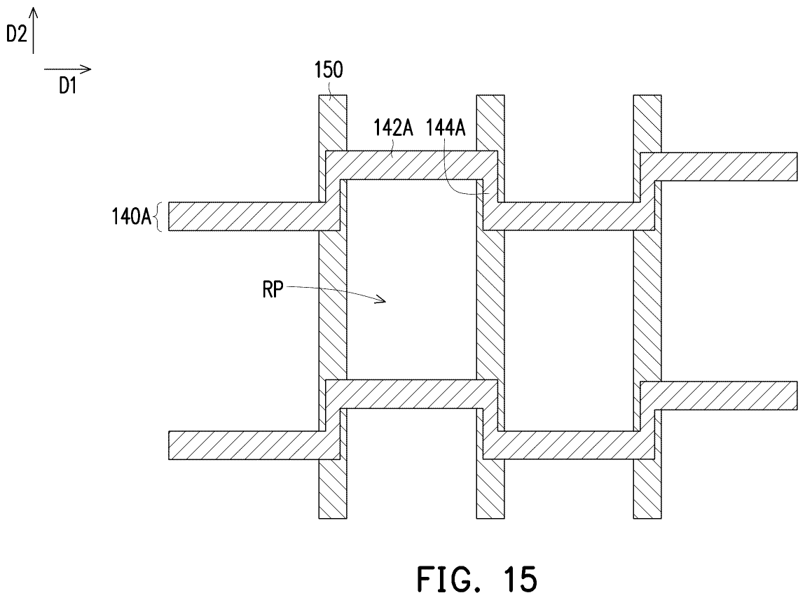

FIG. 15 is a schematic top view of a first light-shielding strip and a second light-shielding strip in an electronic device according to another embodiment of the disclosure. Referring to FIG. 15, the first light-shielding strip 140A is, for example, a bent member in the present embodiment. The second light-shielding strip 150 is an elongated member. In particular, the first light-shielding strip 140A may include a first line segment 142A and a second line segment 144A. The first line segment 142A may be a line segment extending along a first direction D1, and the second line segment 144A may be a line segment extending along a second direction D2. However, the first light-shielding strip 140A still mainly extends along the first direction D1. The second light-shielding strip 150 extends along the second direction D2, the second light-shielding strip 150 may overlap the second line segment 144A of the first light-shielding strip 140A, and the second light-shielding strip 150 may overlap a portion of the first line segment 142A. In some embodiments, the second light-shielding strip 150 may completely block the second line segment 144A of the first light-shielding strip 140A, which is not limited thereto. Pixel regions RP that are arranged in a staggered manner may be defined using the first bent light-shielding strip 140A. For example, in FIG. 15, one of two adjacent pixel regions RP is disposed at an upper location and the other is disposed at a lower location. In this way, the pixel regions RP may be arranged more flexibly and change greatly. In any of the foregoing embodiments, design of the first light-shielding strip 140A may be used, and a bent structure may be disposed in the top view.

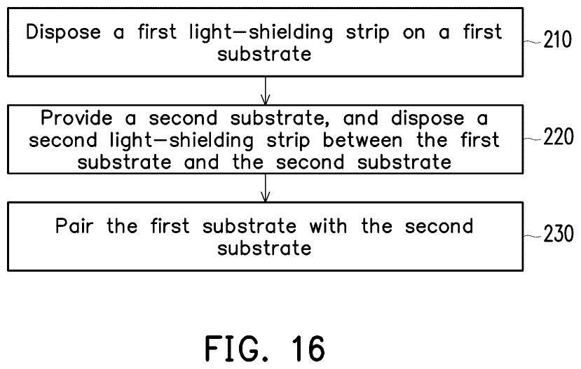

In all of the foregoing embodiments, the first light-shielding strip and the second light-shielding strip in the electronic device may be made of different film layers. Therefore, a method for manufacturing an electronic device according to an embodiment of the disclosure is shown in FIG. 16. In a step 210, a first light-shielding strip is disposed on a first substrate. The first light-shielding strip may extend along a first direction. The first substrate may be a light transmissive substrate as described in the foregoing embodiments. In some embodiments, the first light-shielding strip may be made of a photoresist material. In this case, the method for manufacturing the first light-shielding strip may include: first coating the photoresist material on the first substrate, and then patterning the photoresist material layer using a lithography (yellow light) process, so as to obtain the first light-shielding strip after the photoresist material is developed and solidified. In other embodiments, the first light-shielding strip may be made of metal. In this case, the method for manufacturing the first light-shielding strip may include: first depositing the metal material on the first substrate, and then patterning a metal material layer on the first substrate, where a method for patterning the metal material layer includes, for example, a photolithography etching process or other suitable processes.

In step 220, a second substrate may be provided, and a second light-shielding strip is disposed between the first substrate and the second substrate. The second light-shielding strip may extend along a second direction, and the first direction may be different from the second direction. The second substrate herein may also be a light transmissive substrate. A method for manufacturing the second light-shielding strip is similar to the foregoing method for manufacturing the first light-shielding strip. When the second light-shielding strip is made of a photoresist material, the second light-shielding strip may be manufactured, for example, through a lithography process. When the second light-shielding strip is made of a metal material, the second light-shielding strip may be manufactured, for example, through a deposition process and the photolithography process. When the second light-shielding strip is manufactured on the first substrate, structures of the second light-shielding strip and the first light-shielding strip may be shown in any of the foregoing FIG. 6 to FIG. 10, FIG. 13A, FIG. 13B, and FIG. 14. When the second light-shielding strip is manufactured on the second substrate, structures of the second light-shielding strip and the first light-shielding strip may be shown in any of the foregoing FIG. 11 and FIG. 12. Distribution and arrangement of the first light-shielding strip and the second light-shielding strip in a top view may be shown in FIG. 2 or FIG. 15. In addition, a manufacturing order of step 210 and step 220 may be adjusted depending on different demands. In some embodiments, step 220 may be performed before step 210, and in other embodiments, step 210 may be performed before step 220.

In step 230, the first substrate and the second substrate are paired. In particular, the first substrate and the second substrate are paired after the first light-shielding strip and the second light-shielding strip are manufactured. In some embodiments, a spacer layer may be disposed between the first substrate and the second substrate, and the first substrate is paired together using a sealant. The spacer layer may be the spacer layer PS as described in the foregoing embodiments, which separates the first substrate from the second substrate by a certain distance. The sealant is a solidified adhesive material. For example, the sealant may enclose a frame-shaped pattern, and a medium is filled into a space surrounded by the sealant before the sealant is completely solidified. Next, the first substrate and the second substrate may be configured to clamp the sealant and solidify the sealant. In some embodiments, the sealant may be a discontinuous structure, which is not limited thereto. When the medium is a liquid crystal material, a method for filling the medium may include a dropping injection method or a vacuum injection method. When the medium is an organic light-emitting material, the medium may be manufactured through evaporation or printing. In addition, in some embodiments, the medium may be a film-like structure, such as an electrophoretic film, and the medium may be attached to the first substrate or the second substrate.

Following step 230, a plurality of first light-shielding strips and a plurality of second light-shielding strips may be located between the first substrate and the second substrate. The plurality of first light-shielding strips extends along the first direction, and the plurality of second light-shielding strips extends along the second direction, the first direction intersecting the second direction. In addition to the foregoing step 210 and step 220, before step 230 is performed, members such as a color filter pattern, a planarization layer, and an interface layer may further be disposed on the first substrate. In addition, the structure shown in FIG. 12 may also be disposed on the second substrate. Definitely, before the step 230 is performed, other necessary structures may further be formed between the first substrate and the second substrate, which is not limited thereto in the disclosure.

Based on the above, according to the electronic device of the embodiments of the disclosure, the first light-shielding strip and the second light-shielding strip are respectively manufactured using different film layers, and the first light-shielding strip overlaps the second light-shielding strip, so that an overlapping region is defined. In the overlapping region, because the first light-shielding strip overlaps the second light-shielding strip, a total thickness of the first light-shielding strip and the second light-shielding strip in the overlapping region is different from a thickness of the first light-shielding strip in a non-overlapping region, and the total thickness is also different from a thickness of the second light-shielding strip in the non-overlapping region. Therefore, the first light-shielding strip and the second light-shielding strip are disposed in the embodiments of the disclosure, which helps improve quality of the electronic device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device comprising:
a first substrate;
a second substrate disposed opposite to the first substrate;
a first light-shielding strip disposed on the first substrate and extending along a first direction;
a second light-shielding strip disposed between the first substrate and the second substrate and extending along a second direction, the first direction being different from the second direction; and
a plurality of color filter patterns disposed on the second light-shielding strip,
wherein a portion of the first light-shielding strip overlapping a portion of the second light-shielding strip is defined as an overlapping region, the other portion of the first light-shielding strip outside the overlapping region is defined as a first non-overlapping region, the other portion of the second light-shielding strip outside the overlapping region is defined as a second non-overlapping region, the overlapping region has a total thickness, the second light-shielding strip has a thickness in the second non-overlapping region, and the total thickness is different from the thickness, and
wherein in a cross-section view, a part of the plurality of color filter patterns comprises a convex portion corresponding to the first light-shielding strip or the second light-shielding strip.

2. The electronic device according to claim 1, wherein the total thickness is greater than the thickness.

3. The electronic device according to claim 1, wherein the plurality of color filter patterns are disposed between the first light-shielding strip and the second substrate.

4. The electronic device according to claim 1, further comprising a spacer layer disposed between the first substrate and the second substrate.

5. The electronic device according to claim 1, wherein in the overlapping region, the first light-shielding strip is in contact with the second light-shielding strip.

6. The electronic device according to claim 5, wherein in the overlapping region, the first light-shielding strip is located between the second light-shielding strip and the first substrate, and the second light-shielding strip has a thickness tapered region between the overlapping region and the second non-overlapping region.

7. The electronic device according to claim 1, wherein the convex portion is corresponding to the overlapping portion of the first light-shielding strip and the second light-shielding strip.

8. The electronic device according to claim 1, wherein the first light-shielding strip or the second light-shielding strip comprising a bent portion.

9. A method for manufacturing an electronic device, the method comprising:
disposing a first light-shielding strip on a first substrate;
providing a second substrate, and disposing a second light-shielding strip between the first substrate and the second substrate;
forming a plurality of color filter patterns on the second light-shielding strip; and
pairing the first substrate with the second substrate,
wherein a portion of the first light-shielding strip overlapping a portion of the second light-shielding strip is defined as an overlapping region, the other portion of the first light-shielding strip outside the overlapping region is defined as a first non-overlapping region, the other portion of the second light-shielding strip outside the overlapping region is defined as a second non-overlapping region, the overlapping region has a total thickness, the second light-shielding strip has a thickness in the second non-overlapping region, and the total thickness is different from the thickness, and
wherein in a cross-section view, a part of the plurality of color filter patterns comprises a convex portion corresponding to the first light-shielding strip or the second light-shielding strip.

10. The method for manufacturing the electronic device according to claim 9, further comprising disposing a spacer layer between the first substrate and the second substrate.

11. The method for manufacturing the electronic device according to claim 9, wherein the convex portion is corresponding to the overlapping portion of the first light-shielding strip and the second light-shielding strip.

12. The method for manufacturing the electronic device according to claim 9, wherein the first light-shielding strip or the second light-shielding strip comprising a bent portion.
